(19) United States
(12) Patent Application Publication
(10) Pub. No.: US 2018/0273802 A1
(43) Pub. Date: Sep. 27, 2018

(54) POLISHING COMPOSITION USING AMINO ACIDS

(71) Applicant: FUJIMI INCORPORATED, Kiyosu-shi (JP)

(72) Inventors: Jimmy Erik Granstrom, Tualatin, OR (US); Hisashi Takeda, Tualatin, OR (US)

(73) Assignee: FUJIMI INCORPORATED, Kiyosu-shi (JP)

(21) Appl. No.: 15/923,384

(22) Filed: Mar. 16, 2018

Related U.S. Application Data
(60) Provisional application No. 62/474,345, filed on Mar. 21, 2017.

(51) Int. Cl. C09G 1/02; C09K 3/14; B24B 37/04; H01L 21/321; H01L 21/768

(52) U.S. Cl. CPC C09G 1/02; C09K 3/14; H01L 23/53238; H01L 21/3212; H01L 21/7684; B24B 37/044

(57) ABSTRACT

Provided herein are methods and compositions for chemical mechanical polishing (CMP) of copper (Cu) and ruthenium (Ru) barrier films in the fabrication of Cu interconnect wiring through damascene process. Particularly useful application of the present methods and composition is during fabrication of fine Cu lines in Ru patterned substrates. The present method and composition involve the use of complexing agent having at least one carboxyl group and at least one amino group, and preferably a hydrophobic side chain.

### CROSS-REFERENCE TO RELATED APPLICATIONS

This application claims the benefit of and priority to U.S. Provisional Patent Application No. 62/474,345, filed Mar. 21, 2017, which is hereby expressly incorporated by reference in its entirety.

### TECHNICAL FIELD

The present technology generally relates to chemical mechanical polishing (CMP) of metal for microelectronic applications. The present technology is especially useful for polishing copper and barrier films in the fabrication of narrow copper interconnect wiring through damascene processes. More particularly, the present technology relates to methods and polishing compositions for polishing copper and barrier films containing ruthenium.

### BACKGROUND

Copper has lower resistivity and better electromigration resistance than metals commonly used in microelectronics. Semiconductor integrated circuits (IC) with copper interconnect wiring provide higher speed performance and better reliability. Copper has become the preferred metal for interconnect wiring in semiconductor IC with feature size of a few microns.

CMP is an important part of damascene process flow in the copper interconnects fabrication. The chemical compositions of CMP slurries are critical to the performance of the copper and barrier metal CMP process. The slurries generally comprise abrasive(s) which provide mechanical abrasion action in the metal polishing, as well as chemical agents that interact with metal film surface so that the polishing removal rate and corrosion rate can be controlled.

It was recently demonstrated that Cu shows faster dissolution in the presence in Ru, causing Cu recess at the Cu and Ru junction after CMP. R. Patolla et al. ICPT 2015 IBM. The Ru recess phenomenon causes serious problems particularly for fabricating narrow Cu lines in Ru patterned substrates.

Thus, there exists the need for determining the root cause of the observed Cu recess during Cu/Ru CMP, and developing new methods and products for Cu/Ru polishing that suppress or avoid the Cu loss.

### SUMMARY OF THE DISCLOSURE

In one aspect, provided herein are methods and related composition for chemical mechanical polishing a substrate comprising a surface having at least one Cu and Ru junction. Particularly, the method comprises contacting the surface with a polishing pad; delivering polishing composition according to the present disclosure to the surface, and polishing said surface with the polishing composition.

In a related second aspect, provided herein are methods for suppressing copper recession at a copper and ruthenium junction during CMP. The method comprises applying to the copper and ruthenium junction a polishing composition according to the present disclosure; and polishing the copper and ruthenium junction.

In a related third aspect, provided herein are methods for preventing copper corrosion in the presence of ruthenium during CMP. The method comprises using for the polishing composition according to the present disclosure.

In a related fourth aspect, provided herein are systems for CMP. The systems comprise a substrate comprising at least one copper and ruthenium junction; a polishing pad, and a polishing composition according to the present disclosure.

In a related fifth aspect, provided herein are substrates comprising a copper line with one or more ruthenium barriers, wherein the substrate is in contact with a polishing composition according to the present disclosure.

In a related sixth aspect, provided here are polishing compositions for use in the present methods. Particularly, the present composition comprises at least one abrasive and at least one complexing agent. Particularly, the complexing agent comprises at least one amino group and one carboxyl group.

In some embodiments, the at least one complexing agent further comprises a carbon-containing side chain having a carbon weight ratio (CWR) of at least 0.7.

In some embodiments, the present composition comprises at least one abrasive and at least one complexing agent, and the at least one complexing agent comprises at least one amino acid of hydrophobicity lower than −1.5 on the Hoop and Woods scale, and pH of the polishing composition is above 8.

In some embodiments, the present composition comprises at least one abrasive and at least one complexing agent. Particularly, the complexing agent is selected from the group consisting of phenylalanine, proline, tryptophan, tyrosine, and analogs thereof, and the polishing composition comprises 0.01%-2% by weight of the complexing agent, and pH of the polishing composition is above 8.

In some embodiments, the present composition comprises at least one abrasive and at least one complexing agent. Particularly, the complexing agent comprises at least one amino group and one carboxyl group, and the polishing composition is suitable for polishing under an alkaline condition a substrate surface comprising at least one copper and ruthenium junction.

In some embodiments, the present composition comprises at least one complexing agent having a carbon-containing side chain, and pKa of the carbon-containing side chain is 0.

In some embodiments, pH of the present composition is above 8. In some embodiments, the pH of the present composition ranges from about 9 to about 11.

In some embodiment, the complexing agent of the present composition is an amino acid having an isoelectric point (IEP), and the difference between the isoelectric point and pH of the polishing composition (pH−IEP) is in the range of about 3-5. Particularly, in some embodiments, the IEP of the complexing agent is in the range of about 5-7.

In some embodiments, the complexing agent of the present composition is an amino acid comprising at least one hydrophobic side chain. Particularly, in some embodiments, hydrophobicity of the amino acid is lower than −1.5 on the Hoop and Woods scale. More particularly, in some embodiments, the complexing agent of the present composition is selected from the group consisting of phenylalanine, proline, tryptophan, tyrosine, isoleucine, valine, methionine, and analogs thereof.

In some embodiments, the present composition is devoid of corrosion inhibitor. In other embodiments, the present composition further comprises about 0.01% to about 1% by weight of a corrosion inhibitor. Particularly, in some embodiments, a weight ratio between the corrosion inhibitor to the complexing agent is less than 50. Further, in some embodiments, the corrosion inhibitor contained in the present composition is a triazole based compound. More particularly, in some embodiments, the corrosion inhibitor is benzotriazole (BTA).

In some embodiments, the present composition further comprises at least one oxidizing agent selected from the group consisting of hydrogen peroxide, and ammonium persulfate.

In some embodiments, the present composition further comprises at least one abrasive selected from the group consisting of alumina abrasive, silica abrasive and ceria abrasive.

In some embodiments, the present composition is a concentrate composition configured for diluting by suitable solvent before using in CMP. In other embodiments, the present composition is a polishing composition readily applicable during CMP.

In some embodiments, the present composition is capable of etching copper at a static etch rate of less than 10 angstrom per minute at room temperature. In some embodiments, the present composition has a copper to ruthenium selectivity of about 0.5 to about 3. In some embodiments, the present methods provide a Cu removal rate of less than 400 A/min.

In some embodiments, the present methods and systems are used for polishing a substrate surface comprising at least one copper and ruthenium junction, thereby suppressing Cu recess at the copper and ruthenium junction. Particularly, in some embodiments, the present method reduces at least 50% copper recession at the copper and ruthenium junction relative to a polishing composition devoid of the complexing agent. In some embodiments, the substrates polished by the present methods are devoid of any copper recess at the copper and ruthenium junction.

In some embodiments, the present methods are used for polishing a Ru-patterned substrates having copper in direct contact with Ru. Particularly, in some embodiments, the substrates have at least one copper and ruthenium junction, and a dimension of copper surface at the copper and ruthenium junction is less than 10 nm. More particularly, the dimension of copper surface at the copper and ruthenium junction is about 7 nm to about 10 nm.

### BRIEF DESCRIPTION OF THE DRAWINGS

FIG. 1 is a scanning transmission electron microscopy (STEM) image showing Cu protrusion in Ta patterned wafers after chemical mechanical polishing (CMP) using the Slurry A composition.

FIGS. 2A-2D are STEM images showing varied level of Cu loss in Ru patterned wafers after CMP using the Slurry A.

FIGS. 3A-3C illustrate that several possible mechanisms are likely not the underlying cause for the observed Cu recess during CMP.

FIGS. 4A-4C illustrate the proposed mechanism and solution for Cu recess during CMP.

FIGS. 5A and 5B show Cu static etching rate at room temperature for a BTA-free Slurry A containing different candidate recess suppressors.

FIGS. 6A and 6B show a relationship between the Cu recess suppressing effect and the isoelectric point (IEP) of a complexing agent.

FIG. 7 shows that the carboxyl group of a complexing agent functions to adsorb the compound on to the Cu surface, and terminal functional groups and/or side chains of the complexing agent affect the Cu etching rate of slurry containing the complexing agent.

FIG. 8 shows side chains of a few amino acids according to exemplary embodiments of the present disclosure.

FIGS. 9A and 9B show the correlation between the recess suppressing effect and the carbon weight ratio (CWR) of a complexing agent according to exemplary embodiments of the present disclosure.

FIG. 10 shows a correlation between the Cu static etch rate of an amino acid-containing Slurry B. The hydrophobicity of the amino acid as measured by the Hoop and Woods scale.

FIG. 11 shows Cu surface after dipping in different slurries: (A) BTA-containing Slurry A containing citric acid (50° C. for 120 minutes); (B) BTA-free Slurry A containing citric acid (50° C. for 15 minutes); (C) BTA-containing Slurry B containing phenylalanine (50° C. for 120 minutes); and (D) BTA-free Slurry B containing phenylalanine (50° C. for 15 minutes).

FIG. 12 shows Cu recess at the Cu and Ru junction after CMP using the Slurry A and Slurry B compositions, respectively.

### DETAILED DESCRIPTION

In one aspect of the present disclosure, provided herein are methods for chemical mechanical polishing (CMP) of a substrate comprising a surface comprising at least one Cu and Ru junction. The method comprises contacting the surface with a polishing pad, delivering a polishing composition to the surface, and polishing the surface with the polishing composition.

In some embodiments, the present CMP method and polishing compositions are used to polish a Ruthenium (Ru) patterned substrate, in which Ru forms a barrier film around Cu interconnects, thus forming at least one Cu and Ru junction. In some embodiments, the Cu is in direct contact with Ru at the Cu and Ru junction.

In some embodiments, the substrate to be polished comprises very fine Cu lines of a few to a few hundred nanometers (nm) wide. Thus, in some embodiments, at least one dimension of a Cu surface to be polished using the present method and composition is between a few nanometers to a few hundred nanometers. In some embodiments, at least one dimension of a Cu surface to be polished using the present method and composition is below 1 micron. In some embodiments, at least one dimension of a Cu surface to be polished using the present method and composition is below 100 nm. In some embodiments, at least one dimension of a Cu surface to be polished using the present method and composition is below 10 nm. In some embodiments, at least one dimension of a Cu surface to be polished using the present method and composition ranges from about 7 to 10 nm.

In a related aspect of the present disclosure, provided herein are compositions of polishing composition for performing the present CMP methods. According to the present disclosure, the polishing composition contains an aqueous solvent and at least one complexing agent. The term “aqueous solvent” as used herein refers to water, or a solvent mixture of water (>50%) and a water soluble solvent (<50%).

In some embodiments, the present composition is a concentrate composition configured for diluting by a suitable solvent before using in CMP. In other embodiments, the present composition is a polishing composition readily applicable during CMP.

As used herein, the complexing agent is a chemical compound that interacts with surfaces of metals to be polished during CMP. In some embodiments, the complexing agent is a nitrogen (N—) containing compound. Particularly, in some embodiments, the complexing agent comprises at least one amino group.

“Amino groups” as used herein refer to functional groups that contain a basic nitrogen atom having a lone pair and single bonds to hydrogen atom(s) and/or substituent chemical group(s). The substituent chemical group is not specifically limited, and in various embodiments, can be either an organic or inorganic group, such as a halogen group, an alkyl group, an aromatic group or an acyl group. Amines are compounds containing at least one amino group. Particularly, primary amines refer to nitrogen-containing compounds having two hydrogen atoms and one substituent group covalently bonded to the nitrogen. Secondary amines refer to nitrogen-containing compounds having one hydrogen atom and two substituent groups covalently bonded to the nitrogen. Tertiary amines are nitrogen-containing compounds where the nitrogen atom covalently bonded to three substituent groups. Cyclic amines are either secondary or tertiary amines where the nitrogen atom is included in a cyclic structure formed by the substituent groups. Most amino acids are primary amines. Proline is a secondary cyclic amine.

In some embodiments, the complexing agent further comprises at least one carboxyl group having the general formula —(C(═O)OH). In some embodiments, the carboxyl group serves to enhance chemical interaction between the complexing agent and the metal to be polished, for example by adsorbing the complexing agent onto the surface of the metal film.

In some embodiments, the complexing agent has at least one amino group and at least one carboxyl group connected by a chemical linking structure. The chemical linking between the carboxyl group and the amino group of the complexing agent is not specifically limited. In some embodiments, the chemical linking structure between the carboxyl group and the amino group of the complexing agent can be a linear, branched and/or cyclic carbon chain having 1 to 20 carbon atoms. Optionally, the chemical linking structure comprises unsaturated covalent bonds and heteroatoms, such as nitrogen, oxygen, sulfur, phosphate, and/or halogens. Optionally, the carbon chain comprises one or more substituted or unsubstituted aryls, acyls, esters, alkoxyls, alkyls, carbonyls, hydroxyls, etc.

In some embodiments, the complexing agent has a cyclic structure. According to the present disclosure, the cyclic structure may be an aromatic ring or an aliphatic ring. In some embodiments, the cyclic structure may contain a hetero atom. In some embodiments, the cyclic structure may be a condensed ring containing two or more rings. In some embodiments, the hetero atom referred herein may be selected from the group consisting of a nitrogen atom, an oxygen atom, a sulfur atom, and a phosphor atom. In various embodiments, the cyclic structure may be branched or unbranched, saturated or unsaturated. The cyclic structure may have 3 to 12 ring members, particularly, 4 to 7 ring members, and more particularly 5 to 6 ring members. Examples of the cyclic structure formed include a benzene ring, a naphthalene ring, a pyridine ring, a pyridazine ring, a pyrimidine ring, a pyrazine ring, a pyrrole ring, an imidazole ring, a pyrazole ring, a triazole ring, an imidazoline ring, an oxazole ring, an isoxazole ring, a thiazole ring, an isothiazole ring, a cyclohexadiene ring, a cyclohexene ring, a cyclopentaene ring, a cvcioheptatriene ring, a cycloheptadiene ring, and a cycloheptaene ring.

In some embodiments, the chemical linking structure of the complexing agent has one or more functional groups capable of reducing Cu static etch rate by the complexing agent. Optionally, the chemical linking structure is a branched structure having one or more side chains branched off the carbon backbone connecting the carboxyl and amino group. Optionally, the complexing agent has an overall low dipole moment in the environment provided by the polishing composition.

In some embodiments, the one or more functional groups residing on the carbon backbone or side chain(s) of the complexing agent do not ionize or polarize in the environment provided by the polishing composition. In some embodiments, the functional groups residing on the carbon backbone or side chains of the complexing agent do not ionize or polarize in the environment provided by the polishing composition. Particularly, in other embodiments, the slurry pH is adjusted to the range under which the functional groups residing on the carbon backbone or side chains of the complexing agent undergo minimal ionization or polarization.

In some embodiments, ionization of the at least one carboxyl group and at least one amino group in the complexing agent or a net charge of the complexing agent molecule is also controlled. As used herein, the term “isoelectric point” or “IEP” or “pI” refers to the pH at which a particular molecule carries no net electrical charge in the statistical mean. The net charge on the molecule is affected by pH of its surrounding environment and can become more positively or negatively charged due to the gain or loss, respectively, of protons (H⁺). Particularly, in some embodiments, the slurry pH is adjusted to be about 3 to about 5 units greater than the isoelectric point (IEP) of the complexing agent.

In other embodiments, the slurry pH is pre-determined, and complexing agents having suitable IEP values are selected for the polishing composition. For example, in some embodiments, the slurry pH is adjusted to be in the alkaline range, and particularly above about pH 8, and more particularly, between about pH 9 and about pH 11. In one exemplary embodiment, the slurry pH is adjusted to be about pH 9.5. Accordingly, in these embodiments, the IEP of selected complexing agent ranges from about pH 5 to about pH 7.

In some embodiments, the at least one side chain of the complexing agent is hydrophobic. In some embodiments, hydrophobicity of the side chain is measured by the carbon content of the side chain. As used herein, carbon weight ratio (CWR) of a chemical structure, such as a compound or a side chain thereof, refers to the percentage of the molecular weight of the chemical structure that is attributable to the carbon atom(s) contained in the chemical structure. For Example, FIG. 8 shows the chemical structures of phenylalanine, proline and cysteine as well as the side chains of these amino acids. Carbon weight ratio is calculated as follows. For phenylalanine, the molecular weight of the side chain is 91 g/mol, and the total weight of carbon atoms contained in the side chain is 84 g/mol. Accordingly the carbon weight ratio of phenylalanine side chain is 84/91=0.92. Similarly, for proline, the molecular weight of the side chain is 41 g/mol, and the total weight of carbon atoms contained in the side chain is 36 g/mol. According the carbon weight ratio of phenylalanine side chain is 36/41=0.88. Similarly, for cysteine, the molecular weight of the side chain is 47 g/mol, and the total weight of carbon atoms contained in the side chain is 12 g/mol. According the carbon weight ratio of phenylalanine side chain is 12/47=0.26.

Without being bound by the theory, it is contemplated that higher carbon content generally indicates greater hydrophobicity of a compound or a side chain thereof. Accordingly, in some embodiments, the complexing agent comprises at least one carbon-containing side chain having a carbon weight ratio of at least 0.7. In some embodiments, the complexing agent comprises at least one carbon-containing side chain having a carbon weight ratio of at least 0.8. In some embodiments, the complexing agent comprises at least one carbon-containing side chain having a carbon weight ratio of at least 0.9. In some embodiments, the complexing agent comprises at least one carbon-containing side chain having a carbon weight ratio of at least 0.95.

In some embodiments, hydrophobicity of the side chain is measured by the acid disassociation constant (Ka) of at least one functional group residing on the side chain. Without being bound by the theory, it is contemplated that less ionization of functional groups on the side chain generally indicates greater hydrophobicity of the side chain. Accordingly, in some embodiments, the pKa, as the measurement of Ka, of the complexing agent side chain is zero in the environment provided by the polishing composition. In some embodiments, the pKa of the complexing agent side chain is greater than about 5. In some embodiments, the pKa of the complexing agent side chain is greater than about 6. In some embodiments, the pKa of the complexing agent side chain is greater than about 7. In some embodiments, the pKa of the complexing agent side chain is greater than about 8. In some embodiments, the pKa of the complexing agent side chain is greater than about 9. In some embodiments, the pKa of the complexing agent side chain is greater than about 10. In some embodiments, the pKa of the complexing agent side chain is greater than about 11. In some embodiments, the pKa of the complexing agent side chain is greater than about 12. Table 1 shows the isoelectric points and pKa values of the common amino acids.

TABLE 1
pKa and pI values of common amino acids.

| Amino acid | pKa₁* | pKa₂** | pKa₃*** | pI |
|---|---|---|---|---|
| Glycine | 2.34 | 9.60 | — | 5.97 |
| Alanine | 2.34 | 9.69 | — | 6.00 |
| Valine | 2.32 | 9.62 | — | 5.96 |
| Leucine | 2.36 | 9.60 | — | 5.98 |
| Isoleucine | 2.36 | 9.60 | — | 6.02 |
| Methionine | 2.28 | 9.21 | — | 5.74 |
| Proline | 1.99 | 10.60 | — | 6.30 |
| Phenylalanine | 1.83 | 9.13 | — | 5.48 |
| Tryptophan | 2.83 | 9.39 | — | 5.89 |
| Asparagine | 2.02 | 8.80 | — | 5.41 |
| Glutamine | 2.17 | 9.13 | — | 5.65 |
| Serine | 2.21 | 9.15 | — | 5.68 |
| Threonine | 2.09 | 9.10 | — | 5.60 |
| Tyrosine | 2.20 | 9.11 | — | 5.66 |
| Cysteine | 1.96 | 8.18 | — | 5.07 |
| Aspartic acid | 1.88 | 9.60 | 3.65 | 2.77 |
| Glutamic acid | 2.19 | 9.67 | 4.25 | 3.22 |
| Lysine | 2.18 | 8.95 | 10.53 | 9.74 |
| Arginine | 2.17 | 9.04 | 12.48 | 10.76 |
| Histidine | 1.82 | 9.17 | 6.00 | 7.59 |

*pKa₁ = a-carboxyl group
**pKa₂ = a-ammonium ion
***pKa₃ = side chain functional group.

In some embodiments, the complexing agent is an amino acid or analog thereof. The amino acid complexing agent of the present disclosure include but are not limited to α-amino acids, where the amino group is attached to the α-carbon in the carbon backbone connecting the amino group and carboxyl group. For example, in various embodiments, the amino acid complexing agent can be β-, γ-, δ-amino acids, etc. The amino acid complexing agents of the present disclosure include but are not limited to the 20 natural amino acids and derivatives or analog thereof.

As used herein analogs of amino acid include, but are not limited to, amino acid isosteres. In some embodiments, the amino acid isostere comprises a carboxylic acid isostere, an amine isostere, or a combination thereof. In some embodiments, the carboxylic acid group of the amino acid is replaced with carboxylic acid isostere. Non-limiting examples of carboxylic acid isosteres include sulfonic acids, sulfinic acids, hydroxamic acids, hydroxamic esters, phosphonic acids, phosphinic acids, sulfonamides, acyl sulfonamides, sulfonylureas, acylureas, tetrazole, thiazolidinediones, oxazolidinediones, oxadiazol-5(4H)-ones, thiadiazol-5(4H)-ones, oxathidiazole-5(4H)-ones, isoxazoles, tetramic acids, or cyclopentane-1,3-diones. In some embodiments, the amino group of the amino acid is replaced with an amine isostere. Non-limiting examples of amine isosteres include hydroxyl and thiol.

In some embodiments, the amino acid complexing agent according to the present disclosure comprises at least one hydrophobic side chain. Hydrophobicity of the side chain may be measured by carbon weight ratio or pKa as described above. Additionally, hydrophobicity of the side chain may be measured by established amino acid hydrophobicity scale parameters (Table 2). In some embodiments, the amino acid complexing agent according to the present disclosure has a hydrophobicity parameter lower than −1.5 on the Hoop and Woods scale. Particularly, in some embodiments, the complexing agent is phenylalanine, proline, tryptophan, tyrosine, Isoleucine, valine, methionine, analogs thereof or combinations thereof

TABLE 5
Established amino acid hydrophobicity scales.

| Amino | | Eisenberg | Engleman | Kyte and | Hoop and | |
|---|---|---|---|---|---|---|
| Acid | Group | and Weiss | et al. | Doolittle | Woods | Janin |
| Ile | Nonpolar | 0.73 | 3.1 | 4.5 | −1.8 | 0.7 |
| Phe | Nonpolar | 0.61 | 3.7 | 2.8 | −2.5 | 0.5 |
| Val | Nonpolar | 0.54 | 2.6 | 4.2 | −1.5 | 0.6 |
| Leu | Nonpolar | 0.53 | 2.8 | 3.8 | −1.8 | 0.5 |
| Trp | Nonpolar | 0.37 | 1.9 | −0.9 | −3.4 | 0.3 |
| Met | Nonpolar | 0.26 | 3.4 | 1.9 | −1.3 | 0.4 |
| Ala | Nonpolar | 0.25 | 1.6 | 1.8 | −0.5 | 0.3 |
| Gly | Nonpolar | 0.16 | 1.0 | −0.4 | 0.0 | 0.3 |
| Cys | Unch/Polar | 0.04 | 2.0 | 2.5 | −1.0 | 0.9 |
| Tyr | Unch/Polar | 0.02 | −0.7 | −1.3 | −2.3 | −0.4 |
| Pro | Nonpolar | −0.07 | −0.2 | −1.6 | 0.0 | −0.3 |
| Thr | Unch/Polar | −0.18 | 1.2 | −0.7 | −0.4 | −0.2 |
| Ser | Unch/Polar | −0.26 | 0.6 | −0.8 | 0.3 | −0.1 |
| His | Charged | −0.40 | −3.0 | −3.2 | −0.5 | −0.1 |
| Glu | Charged | −0.62 | −8.2 | −3.5 | 3.0 | −0.7 |
| Asn | Unch/Polar | −0.64 | −4.8 | −3.5 | 0.2 | −0.5 |
| Gln | Unch/Polar | −0.69 | −4.1 | −3.5 | 0.2 | −0.7 |
| Asp | Charged | −0.72 | −9.2 | −3.5 | 3.0 | −0.6 |
| Lys | Charged | −1.10 | −8.8 | −3.9 | 3.0 | −1.8 |
| Arg | Charged | −1.80 | −12.3 | −4.5 | 3.0 | −1.4 |

In some embodiments, a polishing composition according to the present disclosure comprises about 0.01% to about 2% by weight of the complexing agent.

In some embodiments, the complexing agent, when incorporated into the polishing composition, exerts the effect of substantially reducing static etch rate of at least Cu. For example, in some embodiments, a polishing composition comprising the present complexing agent shows Cu static etch rate of less than 50 angstrom per minute (A/min), particularly less than 25 A/min, and more particularly less than 10 A/min or 5 A/min at room temperature.

In some embodiments, the complexing agent, when incorporated into the polishing composition, exerts the effect of substantially reducing corrosion and removal rates of at least Cu during CMP. Particularly, according to the present disclosure, CMP process utilizing a slurry comprising the present complexing agent may remove Cu at the removal rate of less than 400 A/min, particularly less than 300 A/min or 200 A/min, and more particularly less than 100 A/min or 50 A/min.

In some embodiments, the complexing agents, when incorporated into the polishing composition, exerts the effect of inhibiting Cu corrosion. Particularly, in some embodiments, such corrosion inhibiting effect of the complexing agent is independent of another Cu corrosion inhibitor. In some embodiment, the present polishing composition has a Cu corrosion rate of less than 10 A/min. In some embodiments, the present polishing composition has a Cu corrosion rate of less than 5 A/min. In some embodiments, the present polishing composition has a Cu corrosion rate of less than 1 A/min.

In some embodiments, the complexing agent, when incorporated into the polishing composition, exerts the effect of substantially suppressing Cu recess at a Cu and Ru junction during CMP, thereby resulting in improved planarity of the polished surface. Particularly, polishing a substrate having at least one Cu and Ru junction with a polishing composition comprising the present complexing agent is able to reduce Cu recess at the Cu and Ru junction. As measured by the depth at the deepest point of the dishing or recess area of Cu, a polishing composition comprising the present complexing agent is able to reduce Cu recess by at least 10%, 20%, 30%, 40% or 50% as comparing to the same polishing composition devoid of the complexing agent.

In some embodiments, the present polishing composition has a Cu to Ru selectivity of less than 1. In some embodiments, the present polishing composition has a Cu to Ru selectivity of less than 0.1.

In some embodiments, the polishing composition according to the present disclosure also comprises at least one abrasive. The abrasive in the polishing composition provides mechanical abrasion during CMP. Exemplary embodiments of abrasive that can be used in connection with the present disclosure include but are not limited to alumina abrasive, silica abrasive, ceria, titanium oxide, zirconia, or mixtures thereof. The preferred abrasives are alumina and silica. In order to reduce scratch defects, the mean particle size of the abrasive is preferably controlled. In some embodiments, the particle size profile of the abrasive is measured by D90, which is a characteristic number given by a particle sizing instrument to indicate that the sizes of 90% of particles are less than the characteristic number. In some embodiments, the mean particle size is less than 0.3 micron and the D90 of the abrasive is less than 1 micron. Particularly, in some embodiments, the mean particle size is in between 0.01 and 0.30 micron and D90 is less than 0.5 micron.

In some embodiments, the polishing composition according to the present disclosure also comprises at least one oxidizing agent. Without being bound by the theory, it is contemplated that oxidizing agent in polishing composition attacks the metal surface to be polished, so that the removal rate may be enhanced. Exemplary oxidizing agents that can be used in connection with the present disclosure include but are not limited to hydrogen peroxide, ammonium persulfate, potassium persulfate, ferric nitrate, potassium permanganate, potassium iodate, periodic acid, or combinations thereof. The amount of the oxidizing agent included in the polishing composition is in the range of 0 to about 30% by weight, and particularly, about 0.01% to 30% by weight, more particularly about 0.05% to 20% by weight or 0.1 to 10% by weight.

In some embodiments, the polishing composition according to the present disclosure also comprises at least one Cu corrosion inhibitor. Without being bound by the theory, it is contemplated that the corrosion inhibitor passivates Cu surface to prevent pitting and other types of corrosion defects during CMP. Exemplary Cu corrosion inhibitors that can be used in connection with the present disclosure include but are not limited to benzotriazole (BTA), 1,2,4-triazole, tetrazole, tolytriazole, 4-carboxybenzotriazole, 5-carboxybenzotriale, mercaptobenzoxazole, 2-mercaptobenzothiazole, 2-mercaptobenzimidazole, and derivatives thereof. Generally, the lower the pH of the slurry, the more corrosion inhibitor is required. The concentration of Cu corrosion inhibitor in the polishing composition of this disclosure can be in a range from 0 to 1% by weight and particularly from about 0.01% to 1% by weight.

In some embodiments, the polishing composition according to the present disclosure also comprises at least one surfactant. Without being bound by the theory, it is contemplated that surfactants can improve surface smoothness of polished metal film and reduce defects. Surfactants can also improve the within-wafer uniformity of removal rate. Non-ionic, anionic, cationic, and Zwitterionic surfactants can all be used. Exemplary surfactants that can be used in connection with the present disclosure include but are not limited to polyethylene glycol sorbitan monolaurate and other polyoxyethylene derivatives of sorbitan esters under trade name “Tween” from Uniqema; polyethylene glycol octadecyl ether and other polyoxyethylene fatty ether under trade name “Brij” from Uniqema; nonylphenol ethoxylates under trade name Tergitol from Dow Chemical; octylphenol ethoxylates under trade name Triton X from Dow Chemical; sodium lauryl sulfate and other surfactants of salts of alkyl sulfate; sodium 1-dodecanesulfonate and other surfactants of salts of alkyl sulfonate; quarternary ammonium salts. The surfactant concentration presented in the copper polishing composition of this disclosure can be in a range from 0 to 1% by weight and preferably from 0.01 to 0.2% by weigh.

In another aspect of the present disclosure, provided herein are methods for suppressing Cu recess at a Cu and Ru junction during CMP. The method comprises applying to the Cu and Ru junction a polishing composition according to the present disclosure.

In a third aspect of the present disclosure, provided herein are methods for preventing Cu corrosion during CMP. The method comprises using for the CMP a polishing composition according to the present disclosure.

In a fourth aspect of the present disclosure, provided herein are a system for CMP. The system comprises at least one Cu and Ru junction, a polishing pad and a polishing composition according to the present disclosure.

In a fifth aspect of the present disclosure, provided herein are substrates in contact with a polishing composition according to the present disclosure. In some embodiments, the substrate comprises a Cu line with one or more ruthenium barriers. Particularly, in some embodiments, the Cu line is in direct contact with Ru, thereby forming a Cu and Ru junction. In some embodiments, the Cu and Ru junction is devoid of any Cu recess. Optionally, the Cu line is of a few to a few hundred nanometers wide. Thus, in some embodiments, at least one dimension of a Cu surface in contact with the polishing composition is between a few to a few hundred nanometers. In some embodiments, at least one dimension of a Cu surface in contact with the polishing composition is below 1 micron. In some embodiments, at least one dimension of a Cu surface in contact with the polishing composition is below 100 nm. In some embodiments, at least one dimension of a Cu surface in contact with the polishing composition is below 10 nm. In some embodiments, at least one dimension of a Cu surface in contact with the polishing composition ranges from about 7 to 10 nm.

### EXAMPLES

### Example 1: Observation of Cu Recess in Ru Patterned Substrates

It was recently demonstrated that Cu shows faster dissolution in the presence of Ru, which results in exacerbated Cu recess, particularly in areas adjacent to Ru. R. Patlolla et al. ICPT 2015 IBM.

A series of experiments were performed to compare Cu loss in Ru patterned wafers and in Ta patterned wafers. Particularly, patterned wafer having Cu lines at 50% density were polished using Slurry A containing SiO2 (high purity colloidal silica) 10 wt %, carboxylic acid (e.g., citric acid) 0.5 wt %, benzotriazole (BTA) 0.2 wt %, ammonium hydroxide 0.2 wt %, potassium hydroxide 0.6 wt % and alkyl ether carboxylic acid (e.g., Akypo RLM25 surfactant) 0.05 wt %. The addition of citric acid to the slurry results in about 300% reduction of Cu corrosion rate (data not shown).

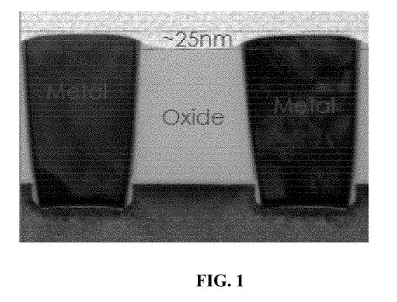

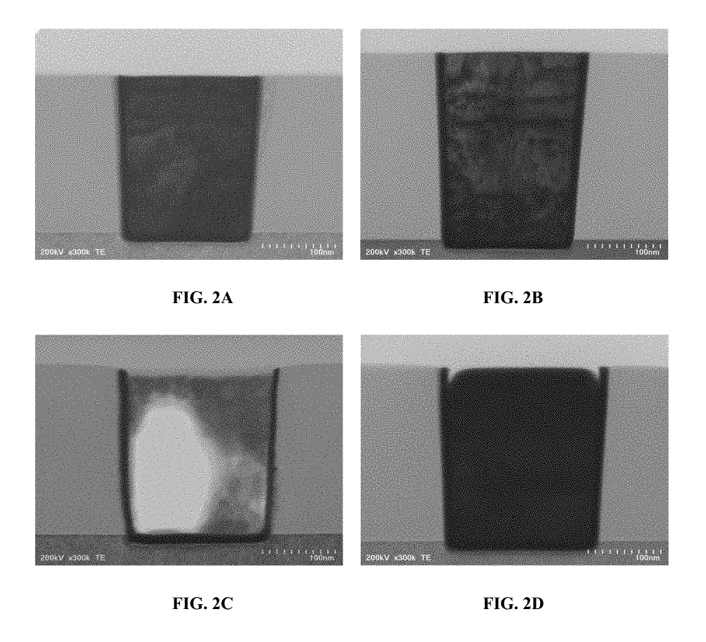

As shown in FIG. 1, no Cu recess at the Cu/Ta junction was observed for Ta barrier wafers. In contrast, as shown in FIGS. 2A-B, a few nanometers Cu recess was observed at the Cu/Ru junctions. Particularly, FIG. 2A shows 2 nm Cu recess at the Cu/Ru junction in the first Ru patterned wafer tested, and FIG. 2B similarly shows 1.3 nm Cu recess at the Cu/Ru junction in a second Ru patterned wafer tested.

Further as shown in FIGS. 2C-D, Cu loss was exacerbated for Ru barrier wafer having isolated Cu lines. Particularly, FIG. 2C shows 10 nm Cu recess at the Cu/Ru junction in a Ru patterned wafer having isolated Cu lines. As shown in FIG. 2D, clear Cu recess was observed at the Cu/Ru junction.

These data indicate that Cu recess is a more severe problem for Ru patterned wafers than Ta patterned wafers.

### Example 2: Establishment of Mechanism for Observed Cu Recess

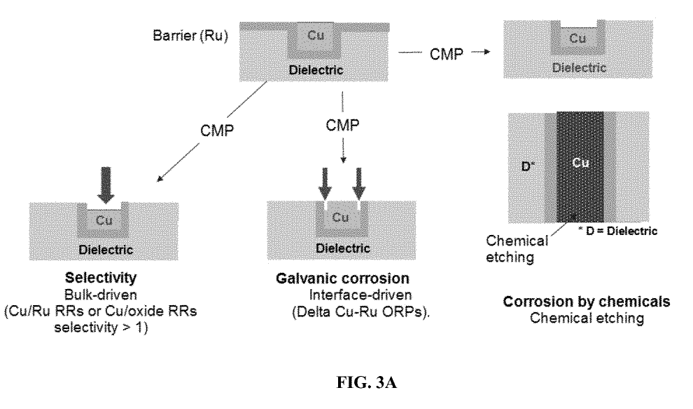

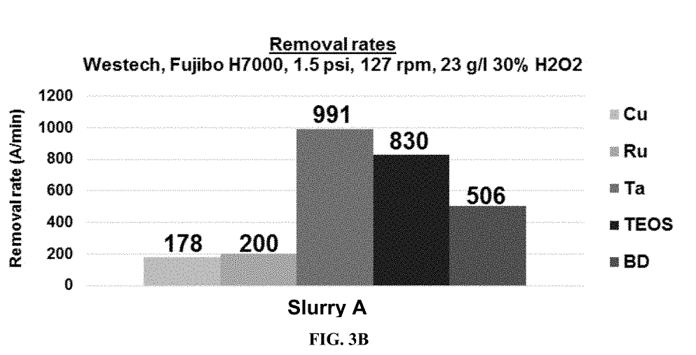

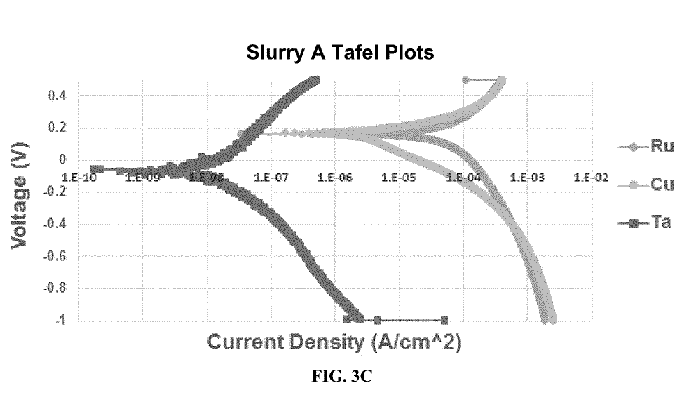

A series of experiments were performed to analyze the mechanism underlying the observed Cu loss. First, Cu to Ru or Cu to dielectric selectivity of the polishing composition was measured. Particularly, removal rates of metals Cu, Ru, 0 measured using the Slurry A on Westech, Fujibo H7000 system at 1.5 psi and 127 rpm. As shown in Table 3 and corresponding FIG. 3B, Cu/barrier or Cu/dielectric selectivity is less than 1. This result excludes selectivity as the cause for the observed Cu recess during CMP (FIG. 3 lower left).

TABLE 3
Measurement of removal rates and selectivity of Slurry A

| | Removal rates (A/min) | | | | | Selectivities (—) | | | |
|---|---|---|---|---|---|---|---|---|---|
| Slurry | Ru | Cu | Ta | TEOS | BD | Cu/Ru | Cu/Ta | Cu/TEOS | Cu/BD |
| Slurry A | 200 | 178 | 991 | 830 | 506 | 0.9 | 0.2 | 0.2 | 0.4 |

Second, as shown in Table 4, the oxidation-reduction potentials (ORPs) for Cu and Ru are found to be matched under the CMP condition, thereby excluding galvanic corrosion as the cause for the observed Cu recess during CMP (FIG. 3 lower center).

Finally, corrosion rates for Cu, Ru and Ta of the Slurry A are measured. Particularly, as shown in Table 4 and corresponding FIG. 3C, corrosion rate of all three metals are very small (<2.5 A/min). Because Cu recess was observed for the polishing composition having a very low Cu corrosion rate, chemical corrosion is likely not a major cause for the observed Cu recess during CMP (FIG. 3 lower right).

These data demonstrate that the mechanisms of high Cu to barrier selectivity, Galvanic corrosion or chemical etching are likely not the underlying cause for the observed Cu recess.

TABLE 4
Measurement of corrosion rates of Slurry A

| | iCorr | Corrosion rate | E (I = 0) |
|---|---|---|---|
| Film | (μA) | (A/min) | (mV) |
| Cu | 4.5 | 1.0 | 162 |
| Ru | 40.0 | 2.5 | 161 |
| Ta | <0.1 | <0.01 | −60 |

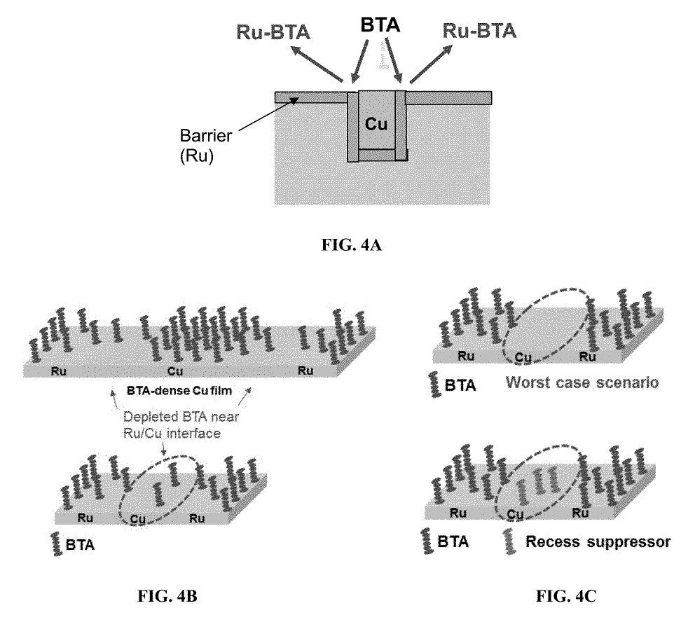

FIGS. 4A and 4B illustrate the proposed mechanism for fast dissolution rate of Cu in presence of Ru. As shown in FIG. 4A, normally corrosion inhibitor BTA contained in the Slurry A and/or interacts with both Cu and Ru to reduce corrosion rate for both metals during CMP. As shown in FIG. 4B upper panel, BTA may be partially depleted on a Cu surface in areas adjacent to the Ru barrier, resulting in fast Cu dissolution in those areas during CMP. As shown in FIG. 4B lower panel, for a fine Cu line, the depletion of corrosion inhibitors may be across its full width, making the depletion more problematic for polishing fine Cu lines in Ru patterned wafers.

The above mechanism suggests the use of another recess suppressor to protect Cu when the conventional corrosion inhibitor molecules are depleted on the Cu surface (FIG. 4C).

### Example 3: Screening for Suitable Cu Recess Suppressors—Nitrogen Content

A series of experiments were performed to identify compounds and chemical properties thereof that are suitable for suppressing Cu recess during Cu/Ru CMP. In an initial screening, Cu static etch rate was measure for BTA-free polishing compositions containing different candidate complexing agents as the recess suppressor. In a first experiment, citric acid, glycine, EDTA and ATMP were tested. Particularly, a candidate complexing agent was added to BTA-free Slurry A to a final molar concentration (n) of 0.026 moles, where n=m/M (m=weight in grams, M=molecular weight in grams/mol), except tyrosine which was only added in the amount of 0.0052 moles due to low solubility. A Cu coupon was merged within the polishing composition for 3 minutes at room temperature, and the change in thickness of the Cu coupon was measured.

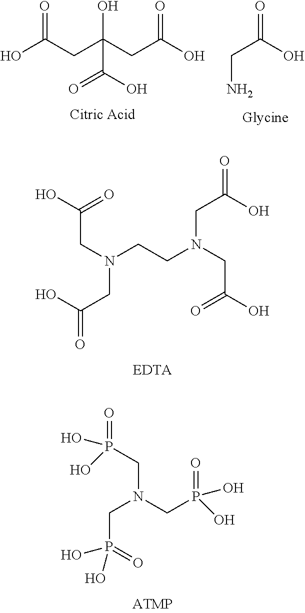

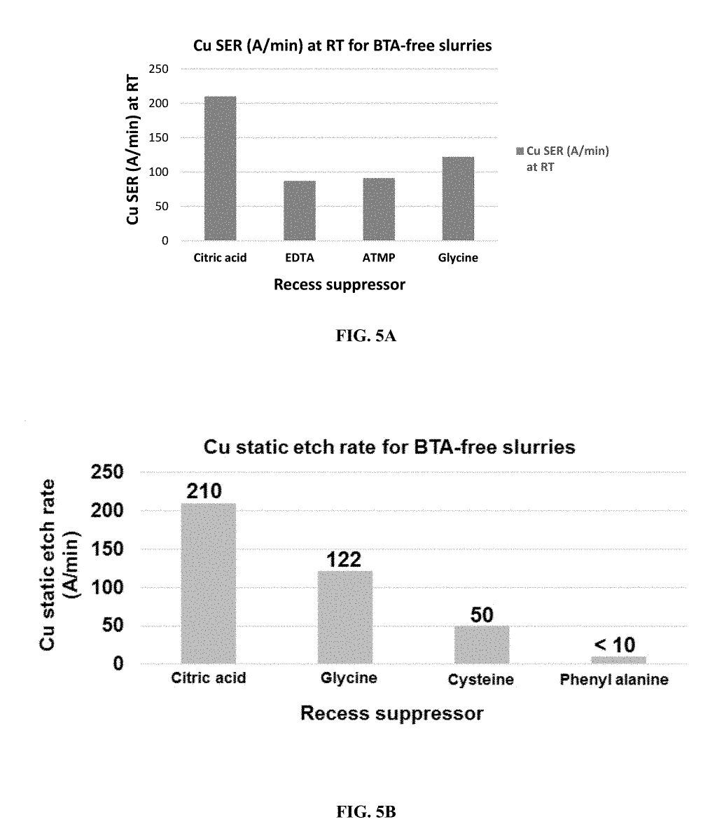

As shown in FIG. 5A, Cu statistic etch rate as measured by the above procedure is 210 A/min for citric acid-containing slurry; 87 A/min for EDTA-containing slurry; 91 A/min for ATMP containing slurry; and 122 A/min for Glycine-containing slurry. All three nitrogen (N) containing compounds have significant lower Cu static etch rates than citric acid, regardless of their respective molecular weights. These data suggest that N-containing compounds may function as good Cu recess suppressors for Cu/Ru CMP.

In a second experiment, citric acid, glycine, cysteine and phenylalanine were tested. As shown in FIG. 5B, phenylalanine and cysteine were able to reduce the polishing compositions' Cu static etch rate to the preferred range of 50 A/min or less at room temperature. Particularly phenylalanine was able to reduce the Cu static etch rate to below 10 A/min.

### Example 4: Screening for Suitable Cu Recess Suppressors—Isoelectric Point (IEP)

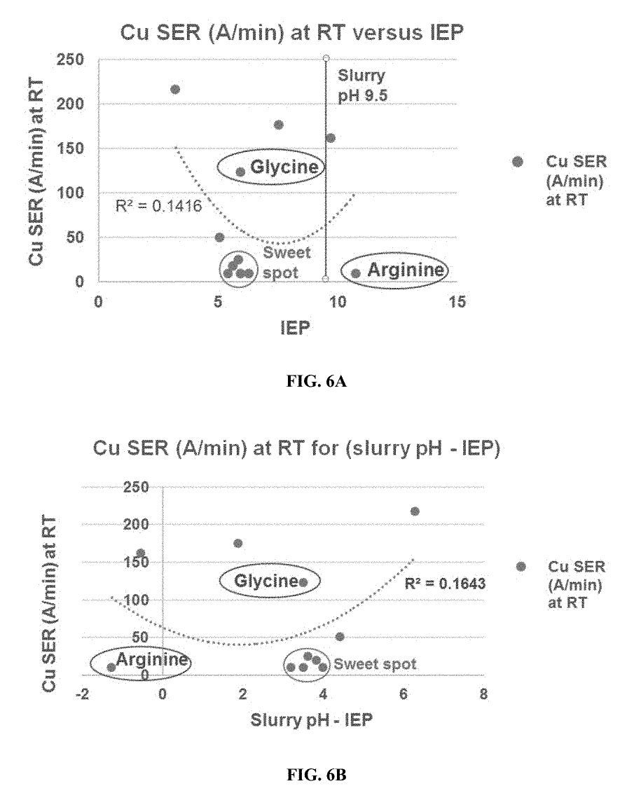

Next, experiments were performed to test whether isoelectric point of a complexing agent correlates with the effect in reducing Cu static etch rate. In this experiment, various amino acids were tested. Particularly, a candidate amino acid was added to BTA-free Slurry A to a final concentration of molar concentration (n) of 0.026 moles, where n=m/M (m=weight in grams, M=molecular weight in grams/mol), except tyrosine which was only added in the amount of 0.0052 moles due to low solubility. The slurry pH was adjusted to pH 9.5. Cu static etch rate was measured as described above. The results were summarized in Table 5 and plotted in FIGS. 6A-6C.

TABLE 5
Effect of amino acids IEP on Cu static etch rate.

| | | Slurry pH - | Cu SER (A/min) | |
|---|---|---|---|---|
| Recess suppressor | IEP | IEP* | at RT | Mw (g/mol) |
| Glutamic acid | 3.22 | 6.28 | 216 | 147 |
| Cysteine | 5.07 | 4.43 | 50 | 121 |
| Phenyl alanine | 5.48 | 4.02 | 10 | 165 |
| Tyrosine | 5.66 | 3.84 | 18 | 181 |
| Tryptophan | 5.89 | 3.61 | 24 | 204 |
| Glycine | 5.97 | 3.53 | 122 | 75 |
| Leucine | 5.98 | 3.52 | 10 | 131 |
| Proline | 6.3 | 3.20 | 10 | 115 |
| Histidine | 7.59 | 1.91 | 175 | 155 |
| Lysine | 9.74 | −0.54 | 161 | 146 |
| Arginine** | 10.76 | −1.26 | 10 | 174 |

*Slurry pH = 9.5
**Glycine was used to titrate the pH to 9.5

Particularly, FIG. 6A plots the Cu static etch rate of an amino acid-containing slurry versus the IEP the amino acid; FIG. 6B plots the Cu static etch rate of an amino acid-containing slurry versus the difference between the slurry pH and the IEP of the amino acid (slurry pH−IEP).

As shown in the figures, no mathematical correlation between complexing agent IEP and Cu static etch rate was observed. However, with the exception of glycine, a preferred IEP range which corresponds to Cu static etch rates below 50 A/min was identified in this study. The preferred IEP range is about 3 to about 4 pH units below the slurry pH (see the sweet spots on FIGS. 6A and 6B). Glycine has the lowest molecular weight amongst all amino acids screened, which may explain the exception for glycine-containing slurries.

### Example 5: Screening for Suitable Cu Recess Suppressors—Carbon Weight Ratio (CWR)

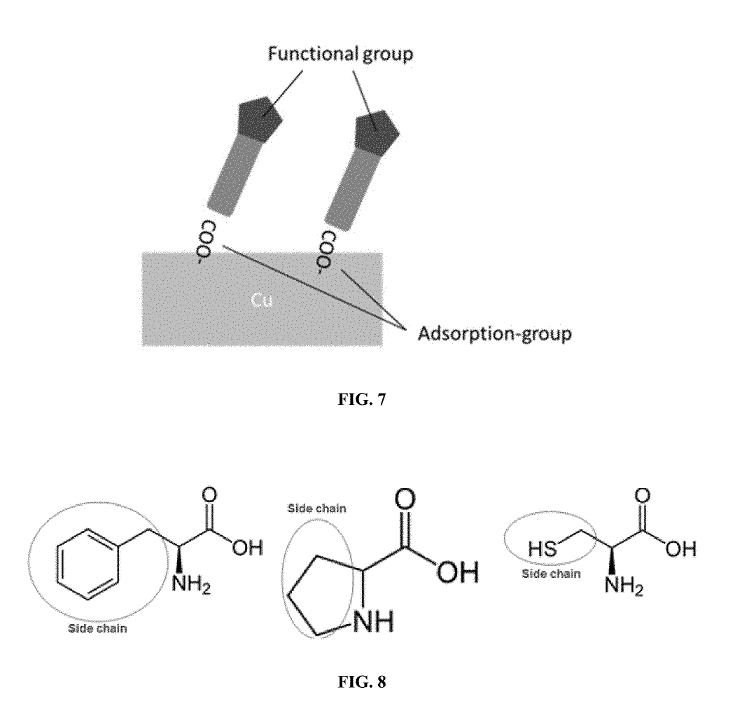

It has been suggested that the value of dipole moment at functional groups of a complexing agent may correlate with the etch rate. Particularly, lower polarity seems to correlate with lower etching rate. As illustrated in FIG. 7, the carboxyl group of a complexing agent functions to adsorb the compound onto the Cu surface, and terminal functional groups and/or side chains of the complexing agent affect the etching rate of polishing composition containing the complexing agent.

Next, experiments were performed to investigate which types of functional groups enable a lower Cu static etch rate at slurry pH 9.5. First hydrophobicity of the complexing agent was examined. In this study, hydrophobicity was measured by the carbon weight ratio and/or pKa of a functional group or side chain of the complexing agent.

A higher carbon weight ratio generally indicates higher hydrophobicity. For example, FIG. 8 shows the side chains of phenylalanine, proline and cysteine. The side chain of phenylalanine has a molecular weight of 91 g/mol, among which the weight of carbon is 84 g/mol. Thus, the carbon weight ratio of the side chain is 0.92 (84/91). Similarly, the carbon weight ratios of side chains of proline and cysteine are 0.88 and 0.26, respectively.

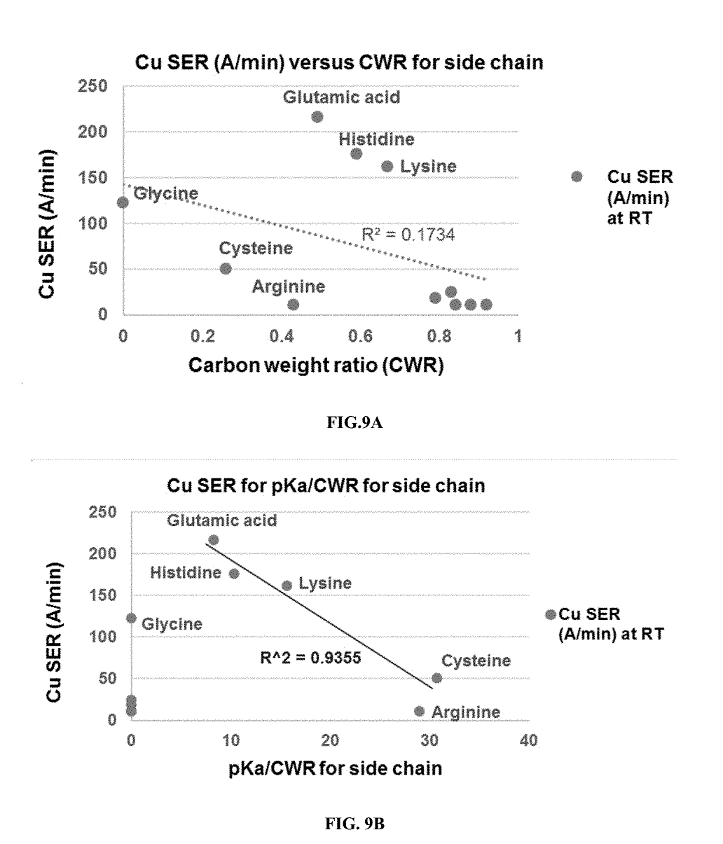

In this experiment, various amino acids were tested. Particularly, a candidate amino acid was added to BTA-free to a final concentration of molar concentration (n) of 0.026 moles, where n=m/M (m=weight in grams, M=molecular weight in grams/mol), except tyrosine which was only added in the amount of 0.0052 moles due to low solubility. The slurry pH was adjusted to pH 9.5. Cu static etch rate was measured as described above. The results were summarized in Table 6 and plotted in FIGS. 9A and 9B.

TABLE 6
Effect of carbon weight ratio of amino acid side chain
on Cu static etch rate.

| | Side chain | | | |
|---|---|---|---|---|
| | | | pKa/carbon | Cu SER (A/min) at |
| Recess suppressor | CWR | pKa | weight | RT |
| Glutamic acid | 0.49 | 4.07 | 8.31 | 216 |
| Cysteine | 0.26 | 8.00 | 30.8 | 50 |
| Phenyl alanine | 0.92 | 0 | 0 | 10 |
| Tyrosine | 0.79 | 0 | 0 | 18 |
| Tryptophan | 0.83 | 0 | 0 | 24 |
| Glycine | No side chain | | | 122 |
| Leucine | 0.84 | 0 | 0 | 10 |
| Proline | 0.88 | 0 | 0 | 10 |
| Histidine | 0.59 | 6.10 | 10.3 | 175 |
| Lysine | 0.67 | 10.53 | 15.7 | 161 |
| Arginine ** | 0.43 | 12.48 | 29.0 | 10 |

Particularly, FIGS. 9A and 9B plot the Cu static etch rates versus the carbon weight ratio and the pKa/CWR ratio, respectively. As shown FIG. 9A, higher carbon weight ratios of the side chains generally enable lower Cu static rate. As shown in FIG. 9B, the etch rate also correlates with the pKa/ratio for amino acids having a pKa above 0. Further, amino acids that have pKa=0 exhibit very low Cu static etch rate. Glycine is an exception in this study, because it does not have any side chain.

In a second study, established amino acid hydrophobicity scales (Table 2) were used as measurements of side chain hydrophobicity.

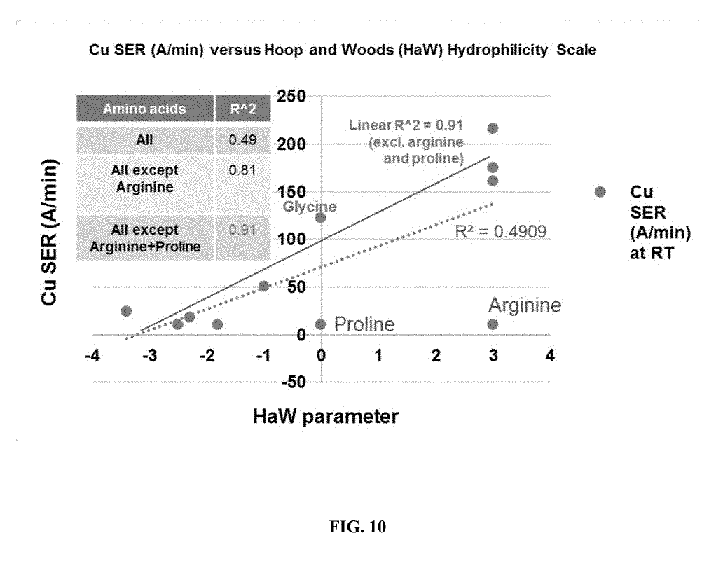

In FIG. 10, Cu static etch rates were plotted versus hydrophobicity parameters of 20 common amino acids according to the Hoop and Woods (HaW), which scale is based on the water solubility of individual amino acids.

As shown in the figure, with the exceptions of proline and arginine, there is a strong correlation between the etch rate and hydrophobicity parameters of amino acids according to the Hoop and Woods scale.

In this study, Arginine-containing slurry has a pH>10, and glycine was used to titrate the slurry pH to pH 9.5. The presence of glycine in the arginine-containing slurry may explain the deviation of arginine. Further, proline is a secondary amino acid, and has only one carbon bonded to the amine nitrogen. The unique structure may explain the deviation of proline in this study.

### Example 6: Screening for Suitable Recess Suppressors—Properties During Chemical Mechanical Polishing

The above research has established that N-containing compounds, such as amino acids, are better than carboxylic acids at protecting Cu in Cu/Ru polishing. The improved Cu protection can be attributed to the amine group, which may better bind to Cu film and Cu ions in solution in an alkaline condition, thus enabling better protection. The —COOH group may also function to adsorb the complexing agent to Cu surface. The presence of a third functional group other than —NH₂ and —COOH of amino acids, preferably having a molecular weight greater than 50, can also contribute to a reduction in Cu static etch rate and Cu corrosion rate. Additionally, longer carbon chain with higher hydrophobicity may further decrease Cu removal rate during CMP in an alkaline regime.

In the following study, BTA-free Slurry A containing different complexing agents are screened for their performance in polishing Ru patterned wafers. Static etch experiments were conducted by immersing samples into each slurry for 3 minutes. Wafer thickness measurements were conducted before and after the test to determine the amount of material removed during the experiment (static etch rate). Corrosion rates were determined with a PARSTAT 2273 potentiostat. Scan rate was 2 mV/sec during the experiment. Corrosion currents were determined from the resulting Tafel plots and calculations for corrosion rates were obtained with Nernst equation. Polishing experiments were conducted with 200 mm blanket wafers on a Westech 372M polisher. The polishing conditions were 1.5 psi, 127 rpm and 200 ml/min.

Table 7 summarizes chemical properties (e.g., molecular weight) of the complexing agents, and Table 8 summarizes performance (e.g. selectivity) of CMP using the candidate slurry.

TABLE 7
Chemical properties of complexing agents.

| | | | Third functional | | Carbon weight | |
|---|---|---|---|---|---|---|
| | Mw | # of | group opposite | Mw third | ratio in Mw | Carbon |
| Complexing | molecule | —NH2/—COOH | —NH2/—COOH | functional | third functional | chain |
| agent | (g/mol) | groups | groups (#) | group (g/mol) | group (—) | length ** |
| Citric acid | 192 | 0/3 | No | — | — | 5 (1) |
| EDTA | 292 | 0/4 | No | — | — | 2 (8) |
| ATMP | 299 | 0/0 | Phosphonate (3) | 81 | — | 0 (3) |
| Glycine | 75 | 1/1 | No | — | 0 | 2 (0) |
| Arginine * | 174 | 1/1 | Guanidinium (1) | 100 | 0.43 | 6 (0) |
| Phenyl alanine | 165 | 1/1 | Benzyl (1) | 91 | 0.92 | 3 (6) |
| Glutamic acid | 147 | 1/2 | Carboxyl (1) | 73 | 0.49 | 5 (0) |
| Cysteine | 121 | 1/1 | Thiol (1) | 47 | 0.26 | 3 (0) |
| Leucine | 131 | 1/1 | Isobutyl (1) | 57 | 0.84 | 5 (1) |
| Histidine | 155 | 1/1 | Imidazole (1) | 81 | 0.59 | 3 (3) |
| Proline | 115 | 1/1 | Pyrrolidine (1) | 41 | 0.88 | 1 (4) |
| Lysine | 146 | 2/1 | Amino (1) | 72 | 0.67 | 6 (0) |
| Tryptophan | 204 | 1/1 | Indole (1) | 130 | 0.83 | 3 (8) |
| Tyrosine | 181 | 1/1 | Hydroxybenzyl | 107 | 0.79 | 3 (6) |

* Glycine was used to titrate to target pH 9.5
** Carbon chain length denotes the backbone of the molecule, with # of carbons for any side chain(s) in parenthesis

TABLE 8
Complexing agent effect
on slurry corrosion performance and removal rates

| | Cu static etch | Cu | | |
|---|---|---|---|---|
| | rate (SER) at | corrosion | Cu | |
| | room | rate at room | removal | Normalized |
| Complexing | temperature | temperature | rate | Ru removal |
| agent | (A/min)*** | (A/min) | (A/min) | rate (—) |
| Citric acid | 210 | 10.8 | 162 | 1.00 |
| EDTA | 87 | N/A | NA | NA |
| ATMP | 91 | N/A | NA | NA |
| Glycine | 122 | 10.7 | NA | NA |
| Arginine* | <10 | 5.3 | 251 | 0.02 |
| Phenyl | <10 | 0.3 | 359 | 0.89 |
| alanine | | | | |
| Glutamic | 216 | 26.0 | NA | NA |
| acid | | | | |
| Cysteine | 50 | 12.6 | 251 | 0.02 |
| Leucine | <10 | 5.3 | 148 | 0.05 |
| Histidine | 175 | 1.6 | 244 | N/A |
| Proline | <10 | 0.6 | 400 | 0.45 |
| Lysine | 161 | 2.9 | N/A | N/A |
| Tryptophan | 24 | 0.8 | 468 | 0.61 |
| Tyrosine**** | 18 | 0.7 | 229 | 0.41 |

*Glycine was used to titrate to target pH 9.5.
***These formulations were prepared without corrosion inhibitor (BTA) to emphasize the effect of the ligands.
****Due to low water solubility, added tyrosine was only ~20% of the other complexors in the study.

As shown in Table 8, at least phenylalanine, proline, tryptophan, tyrosine, leucine are suitable for reducing Ru corrosion and removal rates, while providing suitable Cu/Ru selectivity during CMP of Ru patterned wafers. Particularly, the BTA-free slurry with phenylalanine exhibited the lowest Cu SER or Cu corrosion rate in combination with low Cu and high Ru removal rates.

Further experiments were performed to investigate capability of phenylalanine in suppressing Cu recess in the presence of BTA. Particularly, Cu static etch rate was tested for candidate slurries containing SiO₂ (high quality colloidal silica), ammonium hydroxide, potassium hydroxide, alkyl ether carboxylic acid (e.g., Akypo RLM25 surfactant) and different amounts of BTA and/or phenylalanine. A Cu coupon was immersed in the candidate slurry at 50° C. for 10 minutes, and the change in thickness of the Cu coupon was measured.

As shown in Table 9, in this study, the weight ratio between BTA and phenylalanine was maintained at 50 or below and all candidate slurries have a satisfactory Cu static etch rate.

TABLE 9
Cu SER (50° C.) for slurries containing different amounts of BTA and
phenylalanine.

| | BTA | | BTA/phenyl | Cu SER |
|---|---|---|---|---|
| | amount | Phenyl alanine | alanine | (50 deg. C.) |
| Formulation | (wt-%) | (wt-%) | (—) | (A/min)* |
| A | 0.2 | 0.4 | 0.5 | <1 |
| B | 0.2 | 0 | — | 7 |
| C | 0.05 | 0 | — | 21 |
| D | 0.05 | 0.03 | 1.5 | 2 |
| E | 0.05 | 0.01 | 5 | 5 |
| F | 0.05 | 0.001 | 50 | 20 |

*Cu SER was determined by immersing a Cu coupon into Slurry At 50° C. for 10 minutes.

### Example 7 Corrosion Inhibiting Effect of the Complexing Agent

Next, a series of experiments were performed to examine the corrosion inhibiting effect of the complexing agent.

Particularly Slurry A and Slurry B compositions are prepared with or without BTA. As shown in Table 10, the two polishing compositions contain citric acid and phenylalanine as the candidate recess suppressor, respectively. Other common components of the two compositions are also shown in Table 10. Cu coupons were immersed in the polishing compositions at 50° C. for 120 minutes for slurries containing BTA, and for 15 minutes for slurries prepared without BTA. Citric acid was used in the amount of 0.026 moles (5 wt-%) in Slurry A and phenyl alanine was used in the amount of 0.021 moles (3.43 wt-%) in Slurry B. The amount of phenyl alanine was lower to optimize certain parameters, e.g. reduce Cu removal rate.

TABLE 10
Polishing compositions

| | | BTA | | Al(OH)₃ | Akypo | | Cu |
|---|---|---|---|---|---|---|---|
| | Recess | (corrosion | SiO2 | KOH | RLM25 | | surface |
| Slurry * | suppressor | inhibitor) * | (abrasive) | (oxidizer) | (surfactant) | pH | quality |
| Slurry A | Citric acid | Yes | Yes | Yes | Yes | 9.5 | Good |
| Slurry A | Citric acid | No | Yes | Yes | Yes | 9.5 | Poor |
| Slurry B | Phenyl | Yes | Yes | Yes | Yes | 9.5 | Good |
| | alanine | | | | | | |
| Slurry B | Phenyl | No | Yes | Yes | Yes | 9.5 | Good |
| | alanine | | | | | | |

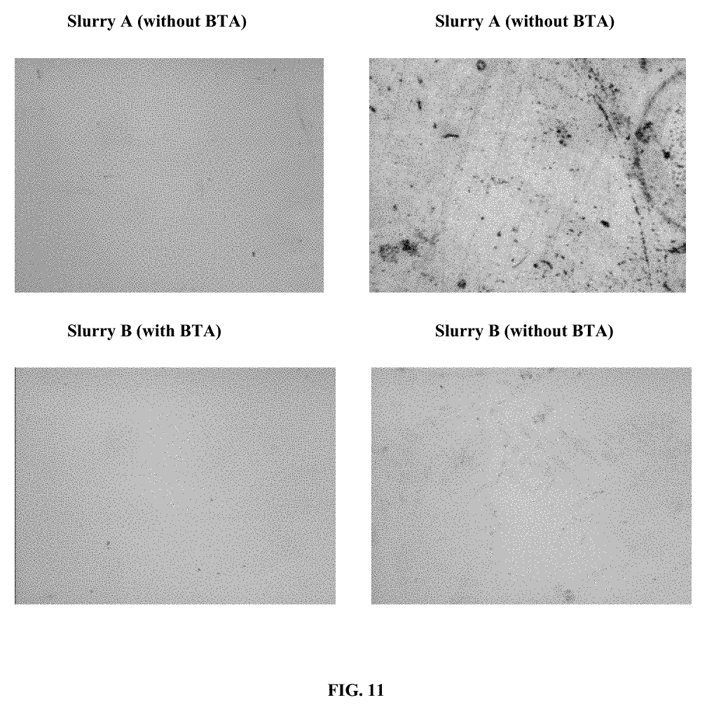

As shown in FIG. 11, phenylalanine is able to improve Cu surface quality even in BTA-free slurry.

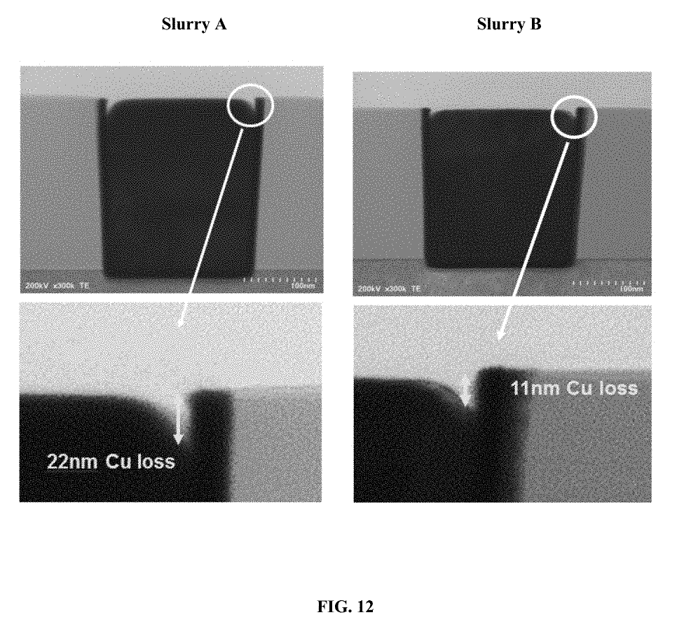

FIG. 12 shows the measurement of Cu corrosion rate for Slurry A composition with or without citric acid. As shown, citric acid helps to reduce Cu corrosion rate in Slurry A, possibly due to competition with ammonia, which contributes to a greater Cu corrosion rate than citric acid. In addition, citric acid may work as a chelator, reducing the recess caused by Cu-ammonia complexes (Garza/Miller CAMP 2012).

### Example 9 Recess Suppressing Effect of the Complexing Agent During CMP

Next, Slurry A and Slurry B compositions are used for CMP of substrates having isolated Cu lines (0.18 μm/0.18 μm) in contact with Ru barrier films. Particularly, the substrate was polished with Slurry A for 62 seconds and with Slurry B for 90 seconds.

As shown in FIG. 12, despite of the shorter polishing time, the substrate polished by Slurry A exhibits greater Cu recess than the Slurry B composition. Particularly, Slurry A polished substrate has a 21.8 nm Cu loss at the Cu and Ru junction, as measured by the depth at the deepest spot of the recess area. In contrast, Slurry B polished substrate has 10.9 nm Cu loss. These data show that Slurry B reduced Cu loss by at least 50% compared with Slurry A. In this experiment, both polishing compositions contained the same amount of BTA.

### EQUIVALENTS

The present technology is not to be limited in terms of the particular embodiments described in this application, which are intended as single illustrations of individual aspects of the present technology. Many modifications and variations of this present technology can be made without departing from its spirit and scope, as will be apparent to those skilled in the art. Functionally equivalent methods and apparatuses within the scope of the present technology, in addition to those enumerated herein, will be apparent to those skilled in the art from the foregoing descriptions. Such modifications and variations are intended to fall within the scope of the present technology. It is to be understood that this present technology is not limited to particular methods, reagents, compounds compositions or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

All numerical designations, e.g., pH, temperature, time, concentration, amounts, and molecular weight, including ranges, are approximations which are varied (+) or (−) by 10%, 1%, or 0.1%, as appropriate. It is to be understood, although not always explicitly stated, that all numerical designations may be preceded by the term “about.” It is also to be understood, although not always explicitly stated, that the reagents described herein are merely exemplary and that equivalents of such are known in the art.

All patents, patent applications, provisional applications, and publications referred to or cited herein are incorporated by reference in their entirety, including all figures and tables, to the extent they are not inconsistent with the explicit teachings of this specification.

1. A method for chemical mechanical polishing (CMP) of a substrate comprising a surface comprising at least one copper and ruthenium junction, the method comprising:
contacting the surface with a polishing pad;
delivering a polishing composition to the surface,
wherein the polishing composition comprises at least one abrasive and at least one complexing agent;
wherein the complexing agent comprises an amino group and a carboxyl group; and polishing said surface with the polishing composition.

2. (canceled)

3. (canceled)

4. The method of claim 1, wherein the complexing agent further comprises at least one carbon-containing side chain having a carbon weight ratio (CWR) of at least 0.7.

5. The method of claim 4, wherein pKa of the carbon-containing side chain is 0.

6. The method of claim 1, wherein pH of the polishing composition is above 8.

7. The method of claim 6, wherein the pH of the polishing composition is about 9 to about 11.

8. The method of claim 4, wherein the complexing agent is an amino acid having an isoelectric point (IEP), and wherein the difference between the isoelectric point and pH of the CMP composition (pH−IEP) is in the range of about 3-5.

9. The method of claim 8, wherein the IEP is in the range of about 5-7.

10. The method of claim 1, wherein the complexing agent is an amino acid comprising at least one hydrophobic side chain.

11. The method of claim 10, wherein hydrophobicity of the amino acid is lower than −1.5 on the Hoop and Woods scale.

12. The method of claim 1, wherein the complexing agent is selected from the group consisting of phenylalanine, proline, tryptophan, tyrosine, isoleucine, valine, methionine, and analogs thereof.

13. The method of claim 1, wherein the complexing agent comprises a cyclic structure.

14. The method of claim 1, wherein the polishing composition comprises 0.01%-2% by weight of the complexing agent.

15. The method of claim 1, wherein the polishing composition has a static etching rate for copper of less than about 10 angstrom per minute at room temperature.

16. The method of claim 1, wherein the method is capable of reducing at least 50% copper recession at a copper and ruthenium junction comparing to a method devoid of the complexing agent.

17-21. (canceled)

22. The method of claim 1, wherein the method is capable of preventing copper corrosion in the absence of corrosion inhibitor.

23. A system for chemical mechanical polishing (CMP) comprising a substrate comprising at least one copper and ruthenium junction; a polishing pad, and a polishing composition, wherein the polishing composition comprises at least one abrasive and at least one complexing agent; and wherein the complexing agent comprises an amino group and a carboxyl group.

24. The system of claim 23, wherein the complexing agent further comprises at least one carbon-containing side chain having a carbon weight ratio (CWR) of at least 0.7.

25-32. (canceled)

33. The system of claim 23, wherein the complexing agent is selected from the group consisting of phenylalanine, proline, tryptophan, tyrosine, isoleucine, valine, methionine, and analogs thereof.

34-37. (canceled)

38. A substrate comprising a copper line with one or more ruthenium barriers, wherein the substrate is in contact with a polishing composition, and wherein the polishing composition comprises at least one complexing agent comprising an amino group and a carboxyl group.

39. The substrate of claim 38, wherein a dimension of the copper line in contact with the polishing composition is less than 10 nm.

40-81. (canceled)
